(19) United States
(12) Patent Application Publication
(10) Pub. No.: US 2024/0261930 A1
(43) Pub. Date: Aug. 8, 2024

(54) SUBSTRATE POLISHING APPARATUS AND METHOD OF POLISHING SUBSTRATE

(71) Applicant: Samsung Electronics Co., Ltd., Suwon-si (KR)

(72) Inventors: Yejin Choi, Suwon-si (KR); Donghoon Kwon, Suwon-si (KR)

(21) Appl. No.: 18/536,321

(22) Filed: Dec. 12, 2023

(30) Foreign Application Priority Data
Feb. 6, 2023 (KR) 10-2023-0015442

(51) Int. Cl. B24B 37/015

(52) U.S. Cl. CPC B24B 37/015

(57) ABSTRACT

A substrate polishing apparatus includes a platen having a surface configured polish through relative movement between the platen and a semiconductor substrate, a slurry supply configured to supply slurry to the platen, wherein the slurry flows to a location between the semiconductor substrate and the platen, a substrate holder configured to grip and fix the semiconductor substrate to be in contact with the platen such that the platen contacts the surface of the semiconductor substrate to be polished, a temperature controller having a thermal conductive body that is configured to contact the surface of the platen to transfer heat between the thermal conductive body and the platen to control the temperature of the platen, and a first cleaner having an ultrasonic transducer and at least one probe, the ultrasonic transducer configured to generate ultrasonic waves and the probe configured to transmit the ultrasonic waves to an outer surface of the thermal conductive body.

### PRIORITY STATEMENT

This application claims priority under 35 U.S.C. § 119 to Korean Patent Application No. 10-2023-0015442, filed on Feb. 6, 2023, in the Korean Intellectual Property Office (KIPO), the contents of which are herein incorporated by reference in their entirety.

### BACKGROUND

### 1. Field

Example embodiments relate to a substrate polishing apparatus and a method of polishing a semiconductor substrate. More particularly, example embodiments relate to a substrate polishing apparatus and a method of polishing a semiconductor substrate through the use of a slurry.

### 2. Description of the Related Art

In a chemical mechanical polishing (CMP) process, temperature control may be required to improve the polishing performance of the CMP process to obtain a highly polished semiconductor substrate. The temperature control may include a non-contact method of spraying a fluid onto a platen and/or a contact method of transferring heat to the platen via a heat conductor. The non-contact method may result in diluting the slurry with the fluid. Since the contact method does not expose a fluid to the platen, the slurry may be undiluted during the CMP process. However, in the contact method, the slurry and pad debris may contact the heat conductor, causing contamination and solidification.

### SUMMARY

Example embodiments provide a substrate polishing apparatus including a cleaner capable of preventing contamination and solidification that occurs in a contact temperature controller.

Example embodiments provide a method of polishing a substrate using the substrate polishing apparatus.

According to example embodiments, a substrate polishing apparatus includes a platen having a surface configured to polish a semiconductor substrate through relative movement between the platen and the semiconductor substrate, a slurry supply configured to supply slurry to the platen, wherein the slurry flows to a location between the semiconductor substrate and the platen, a substrate holder configured to grip and fix the semiconductor substrate to be in contact with the platen such that the platen contacts the surface of the semiconductor substrate to be polished, a temperature controller having a thermal conductive body that is configured to contact the surface of the platen to transfer heat between the thermal conductive body and the platen to control temperature, and a first cleaner having an ultrasonic transducer and at least one probe, the ultrasonic transducer configured to generate ultrasonic waves and the probe configured to transmit the ultrasonic waves to an outer surface of the thermal conductive body.

According to example embodiments, a substrate polishing apparatus includes a platen having a surface configured to polish a semiconductor substrate through relative movement between the platen and the semiconductor substrate, a slurry supply configured to supply slurry between the semiconductor substrate and the platen, a substrate holder configured to grip and fix the semiconductor substrate to be in contact with the platen such that the platen contacts the surface of the semiconductor substrate to be polished, a temperature controller in contact with the surface of the platen, the temperature controller having a thermal conductive body that is configured to absorb or dissipate heat from the surface of the platen, a first cleaner having an ultrasonic transducer and at least one probe, the ultrasonic transducer configured to generate ultrasonic waves, the probe contacting the thermal conductive body to transmit the ultrasonic waves to the thermal conductive body, and a second cleaner having a plurality of cleaning nozzles that are configured to spray a cleaning solution on an outer surface of the thermal conductive body.

According to example embodiments, in a method of polishing a substrate, a semiconductor substrate is polished through interaction between a platen and the semiconductor substrate using a slurry that is supplied on a surface of the platen. Heat is transferred between the surface of the platen to and a thermal conductive body in contact with the platen to control a temperature of the platen. Ultrasonic waves are generated on an outer surface of the thermal conductive body to remove foreign substances that are formed on the outer surface. A cleaning solution is sprayed on the outer surface of the thermal conductive body at a predetermined angle from a direction perpendicular to the surface of the platen to remove the foreign substances.

According to example embodiments, a substrate polishing apparatus may include a platen having a surface configured to perform a polishing process on a semiconductor substrate, a slurry supply configured to supply slurry between the semiconductor substrate and the platen, a substrate holder configured to grip and fix the semiconductor substrate so as to be brought into contact with the platen such that the semiconductor substrate contacts the surface of the platen to be polished, a temperature controller having a thermal conductive body that is configured to contact the surface of the platen to control temperature, and a first cleaner having an ultrasonic transducer and at least one probe, the ultrasonic transducer configured to generate ultrasonic waves, the probe configured to transmit the ultrasonic waves to an outer surface of the thermal conductive body.

Thus, the temperature controller of the substrate polishing apparatus may directly contact the platen to control the temperature on the platen. Since the temperature controller is in direct contact with the platen, the substrate polishing apparatus may prevent dilution of the slurry. Since the substrate polishing apparatus does not spray fluid onto the platen, wastewater may be reduced.

The first cleaner may transmit the ultrasonic waves that are generated from the ultrasonic transducer to the outer surface of the thermal conductive body through the probe. The thermal conductive body may be cleaned through the ultrasonic waves of the first cleaner. The ultrasonic wave may remove foreign substances that are generated from the slurry and pad residue. The ultrasonic wave may remove the foreign substances without affecting the polishing process.

The substrate polishing apparatus may spray a cleaning solution to the outer surface of the thermal conductive body through a cleaning nozzle. The cleaning solution may remove the foreign substances that might not be removed through the ultrasonic waves. The substrate polishing apparatus may efficiently remove the foreign substances on the thermal conductive body through the first and second cleaners. Since the first and second cleaners remove the foreign substances from the thermal conductive body, the temperature controller may efficiently control the temperature of the surface of the platen.

### BRIEF DESCRIPTION OF THE DRAWINGS

Example embodiments will be more clearly understood from the following detailed description taken in conjunction with the accompanying drawings. FIGS. 1 to 12 represent non-limiting, example embodiments as described herein.

FIG. 1 is a perspective view illustrating a substrate polishing apparatus in accordance with example embodiments.

FIG. 2 is a plan view illustrating the substrate polishing apparatus in FIG. 1.

FIG. 3 is a front view illustrating the substrate polishing apparatus in FIG. 1.

FIGS. 4 to 6 are views illustrating the temperature controller and the cleaner in FIG. 2.

FIG. 7 is a plan view illustrating a substrate polishing apparatus including a thermal conductive body having a trapezoidal shape in accordance with example embodiments.

FIGS. 8 to 10 are views illustrating the temperature controller and the cleaner in FIG. 7.

FIG. 11 is a view illustrating a temperature controller including fluid transfer lines having a meander structure.

FIG. 12 is a view illustrating a temperature controller including fluid transfer lines having a spiral structure.

### DETAILED DESCRIPTION OF EXAMPLE EMBODIMENTS

Hereinafter, example embodiments will be explained in detail with reference to the accompanying drawings.

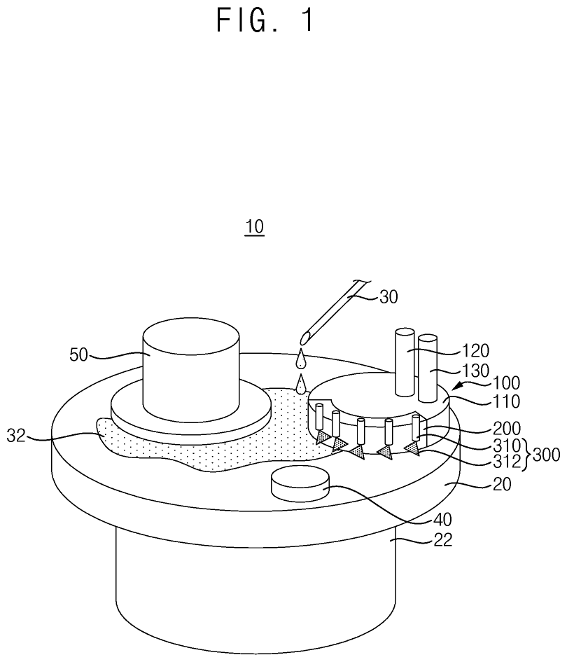

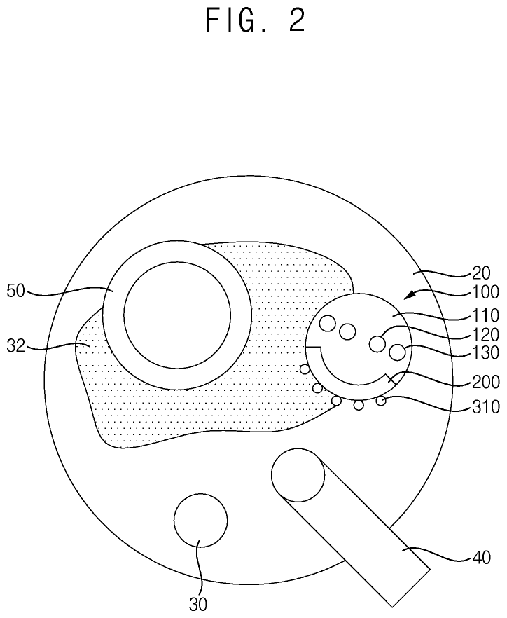

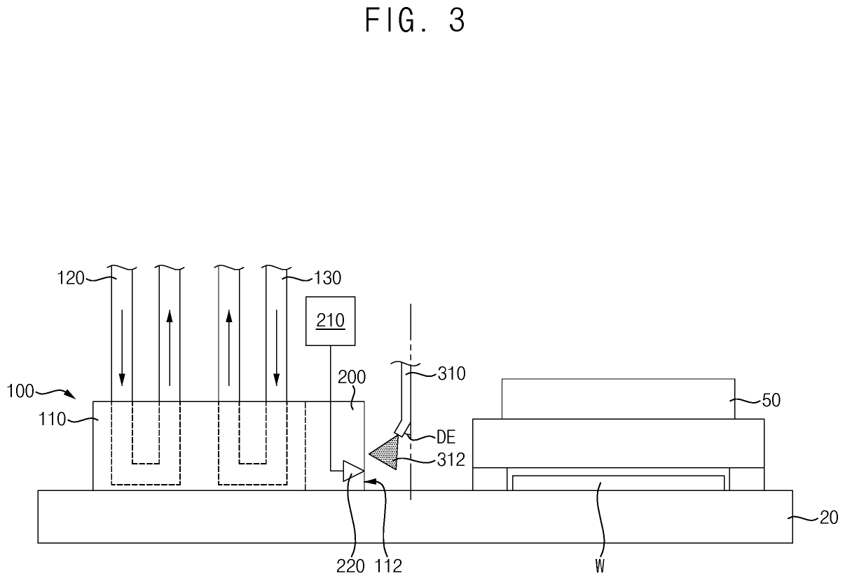

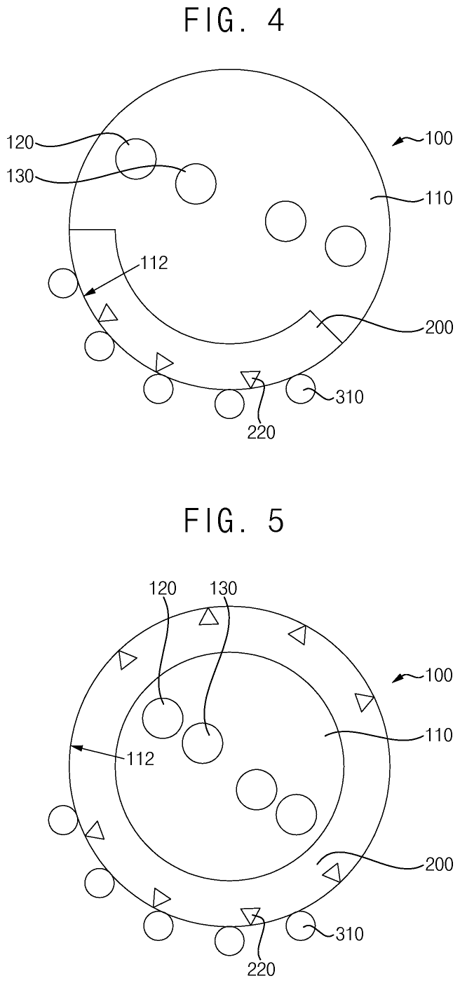

FIG. 1 is a perspective view illustrating a substrate polishing apparatus in accordance with example embodiments. FIG. 2 is a plan view illustrating the substrate polishing apparatus in FIG. 1. FIG. 3 is a front view illustrating the substrate polishing apparatus in FIG. 1. FIGS. 4 to 6 are views illustrating the temperature controller and the cleaner in FIG. 2.

Referring to FIGS. 1 to 6, a substrate polishing apparatus 10 may include a platen 20 configured to support a semiconductor substrate W (visible in FIG. 3), a slurry supply 30 configured to supply slurry 32 to the platen 20 which may then pass to a location between the semiconductor substrate W and the platen 20, a substrate holder 50 configured to hold and fix the semiconductor substrate W on the platen 20 such that the semiconductor substrate W is in contact with the platen 20, a temperature controller 100 configured to control temperature of the platen 20 through a thermal conductive body 110, a first cleaner 200 configured to remove foreign substances on the thermal conductive body 110 through ultrasonic waves, and a second cleaner 300 having at least one cleaning nozzle 310 capable of removing the foreign substances on the thermal conductive body 110 through a cleaning solution.

The substrate polishing apparatus 10 may be referred to as apparatus capable of partially removing one surface of the semiconductor substrate W by a grinding process such as a chemical mechanical polishing (CMP) process. The substrate polishing apparatus 10 may polish a thickness of the semiconductor substrate W to a desired thickness. For example, the semiconductor substrate W may include a wafer.

In example embodiments, the platen 20 may have a surface configured to polish a surface of the semiconductor substrate W. The platen 20 may be supported by shaft 22. The platen 20 may be coupled to the shaft 22 such that rotation of the shaft 22 rotates the platen 20. The platen 20 may be rotated clockwise or counterclockwise by the shaft 22. In the polishing process, the semiconductor substrate W may be disposed on an upper surface of the platen 20.

In the polishing process, an upper or lower surface of the semiconductor substrate W (depending on the orientation of the semiconductor substrate W) and the upper surface of the platen 20 may contact each other or they may have a layer of slurry 32 between the upper or lower surface of the semiconductor substrate W and the upper surface of the platen 20. The terms “contact,” “contacting,” “contacts,” or “in contact with,” as used herein, refers to a direct connection (i.e., touching) unless the context clearly indicates otherwise. The platen 20 may have surface roughness resulting from fine concavo-convex shapes on the upper surface of the platen 20. The surface roughness may be rough enough such that the upper or lower surface of the semiconductor substrate W is polished through the interaction (e.g., relative motion) between the platen 20, the semiconductor substrate W, and the slurry 32.

The platen 20 may rotate by receiving rotational force from the shaft 22 (e.g., the platen 20 may be coupled to the shaft 22 and rotate with the shaft 22). The platen 20 may evenly distribute the slurry 32 on the platen 20 through the rotation of the platen 20. The interaction between the platen 20 and the semiconductor substrate W may generate a frictional force that resists relative movement between the platen 20 and the semiconductor substrate W. The frictional force may be modified by the slurry 32 between the platen 20 and the semiconductor substrate W. In some embodiments, the platen 20 may include a material such as glass, quartz, fused silica, or sapphire.

In example embodiments, the slurry supply 30 may supply the slurry 32 on the platen 20 and the slurry 32 may then pass or flow to a location between the platen 20 and the semiconductor substrate W. The slurry supply 30 may supply the slurry 32 between the semiconductor substrate W and the platen 20. The slurry 32 supplied from the slurry supply 30 may be uniformly applied on the platen 20 through the rotation of the platen 20.

In example embodiments, the slurry 32 may include an aqueous solution having abrasive particles suspended in the aqueous solution. For example, the aqueous solution may include an aqueous phase solution and an aqueous acidic phase solution.

The slurry 32 may further include a booster that adheres to a polishing layer of the semiconductor substrate W to increase polishing strength. The slurry 32 may further include an inhibitor that adheres to the polishing layer of the semiconductor substrate W to reduce the polishing strength. The use of the booster and the inhibitor may vary depending on a material composition of the polishing layer of the semiconductor substrate W.

In example embodiments, the substrate holder 50 may detachably grip and fix the semiconductor substrate W on the platen 20. The substrate holder 50 may fix the semiconductor substrate W in place while the platen 20 moves relative to the semiconductor substrate W. The substrate holder 50 may move relative to the platen 20 causing the semiconductor substrate W to move relative to the platen 20. The substrate holder 50 may fix and transport the semiconductor substrate W to the platen 20. The substrate holder 50 may have a circular shape, sized and shaped, to accommodate the semiconductor substrate W.

The substrate holder 50 may move the semiconductor substrate W on the platen 20. For example, the substrate holder 50 may move horizontally (i.e., in a horizontal direction parallel to the upper surface of the platen 20) and vertically (i.e., in a vertical direction perpendicular to the upper surface of the platen 20) on the platen 20. The substrate holder 50 may press the semiconductor substrate W against the platen 20 in the vertical direction. The substrate holder 50 may press the semiconductor substrate W against the platen 20 to increase the frictional force between the semiconductor substrate W and the platen 20 with the slurry 32 therebetween. In some examples, the platen 20 and the substrate holder 50 may rotate in opposite directions to increase the frictional force by increasing the relative velocity between the platen 20 and the substrate holder 50.

In example embodiments, the temperature controller 100 may include a thermal conductive body 110 in contact with the platen 10 configured to control the temperature of the platen 20, a first fluid transfer line 120 configured to absorb heat from the thermal conductive body 110, and a second fluid transfer line 130 configured to supply heat to the thermal conductive body 110.

The thermal conductive body 110 may contact the surface of the platen 20 to transfer heat between the platen 20 and the thermal conductive body 110 to control the temperature of the platen 20. The thermal conductive body 110 may transfer the heat through a lower surface in contact with the surface of the platen 20. In some examples, the thermal conductive body 110 may have a flat lower surface with a circular shape.

The thermal conductive body 110 may be formed of and/or include a thermal conductive material capable of transferring the heat. For example, the thermal conductive material may include copper (Cu), aluminum (Al), tungsten (W), nickel (Ni), molybdenum (Mo), gold (Au), silver (Ag), chromium (Cr), tin (Sn) and titanium (Ti).

The first fluid transfer line 120 may move a cooling fluid (e.g., water) contained therein to the thermal conductive body. Although not shown in FIG. 1, but shown in FIG. 3, the first fluid transfer line 120 may have a first portion configured to transfer the cooling fluid to the thermal conductive body 110 and a second portion configured to transfer the cooling fluid from the thermal conductive body 110. The first fluid transfer line 120 may extend along the lower surface of the thermal conductive body 110. Since the first fluid transfer line 120 is provided adjacent to the lower surface of the thermal conductive body 110, the first fluid transfer line 120 may absorb the heat that is generated from the platen 20 through contact with the thermal conductive body 110. The first fluid transfer line 120 may transfer the absorbed heat away from the thermal conductive body 110 through the cooling fluid moving away from the thermal conductive body 110.

The second fluid transfer line 130 may move a heating fluid (e.g., water) therein to the thermal conductive body 110. The heating fluid may have a temperature higher than that of the cooling fluid. Although not shown in FIG. 1, but shown in FIG. 3, the second fluid transfer line 130 may have a first portion configured to transfer the heating fluid to the thermal conductive body 110 and a second portion configured to transfer the heating fluid from the thermal conductive body 110. The second fluid transfer line 130 may extend along the lower surface of the thermal conductive body 110. Since the second fluid transfer line 130 is provided adjacent to the lower surface of the thermal conductive body 110, the second fluid transfer line 130 may supply heat to the platen 20 through contact with the thermal conductive body 110. The second fluid transfer line 130 may supply the heat to the thermal conductive body 110 through movement of the heating fluid to the thermal conductive body.

In some embodiments, the first fluid transfer line 120 may transfer a heat transfer fluid to the thermal conductive body 110 and the second fluid transfer line 130 may transfer the heat transfer fluid away from the thermal conductive body 110. A temperature of the heat transfer fluid may be controlled such that the heat transfer fluid heats the thermal conductive body 110 when the temperature of the heat transfer fluid is greater than a temperature of the thermal conductive body 110 or cools the thermal conductive body 110 when the temperature of the heat transfer fluid is less than the temperature of the thermal conductive body 110.

The first and second fluid transfer lines 120 and 130 may receive the cooling fluid and the heating fluid from a fluid supply. The cooling fluid and the heating fluid supplied from the fluid supply may be used to control the temperature of the platen 20, and the used cooling fluid and the used heating fluid may move along the first and second fluid transfer lines 120 and 130 to be recovered.

In example embodiments, the temperature controller 100 may further include an actuator capable of rotating or sweeping the thermal conductive body 110 relative to the platen. The actuator may move the thermal conductive body 110 on the platen 20.

The actuator may move the thermal conductive body 110 to an area where temperature control is required on the platen 20. The actuator may rotate the thermal conductive body 110 on the area where the temperature control is required. The actuator may rotate the thermal conductive body 110 clockwise or counterclockwise. Alternatively, the thermal conductive body 110 may be fixed to a predetermined position on the platen 20.

The actuator may sweep the thermal conductive body 110 within a predetermined angular range. The predetermined angular range may be referred to as an angular range capable of covering the area where the temperature control is required. In processes of loading or unloading the semiconductor substrate W, the actuator may move the thermal conductive body 110 to an outer area of the platen 20. The actuator may prevent a collision between the thermal conductive body 110 and a peripheral device.

In example embodiments, the first cleaner 200 may include an ultrasonic transducer 210 configured to generate ultrasonic waves, and at least one probe 220 configured to transmit the ultrasonic wave to the thermal conductive body 110.

The first cleaner 200 may decompose and/or dislodge foreign substances formed on an outer surface 112 of the thermal conductive body 110. For example, the foreign substances may include the slurry 32 and pad debris. The foreign substances may include a mixture structure that hinders heat transfer of the thermal conductive body 110.

The ultrasonic transducer 210 may generate ultrasonic waves that have a predetermined wavelength suitable to remove (e.g., decompose and/or dislodge) the foreign substances. Vibration may occur on the outer surface 112 of the thermal conductive body 110 from the ultrasonic waves. The mixture structure of the foreign substances may be decomposed and/or dislodged by the vibration. The ultrasonic transducer 210 may be provided in the thermal conductive body 110.

As illustrated in FIG. 3, the probe 220 may be provided in the thermal conductive body 110. The probe 220 may contact the outer surface 112 of the thermal conductive body 110 within the thermal conductive body 110. The probe 220 may receive the ultrasonic waves that are generated from the ultrasonic transducer 210. The probe 220 may transfer the ultrasonic waves to the outer surface 112 of the thermal conductive body 110.

Alternatively, the ultrasonic transducer 210 and the probe 220 may be provided on the thermal conductive body 110. The probe 220 may contact the outer surface 112 of the thermal conductive body 110 from an outside of the thermal conductive body 110 to transfer the ultrasonic waves.

As illustrated in FIG. 4, the first cleaner 200 may be provided along at least a portion of the outer surface 112 of the thermal conductive body 110 where the foreign substances easily occur while the thermal conductive body 110 moves. The first cleaner 200 may remove the foreign substances on at least the portion of the thermal conductive body 110. At least the portion of the thermal conductive body 110 may include a material capable of transmitting the ultrasonic waves.

A body of the first cleaner 200 may have an arc shape corresponding to the circular shape of the thermal conductive body 110. The probe 220 of the first cleaner 200 may be provided on at least the portion of the thermal conductive body 110. The ultrasonic transducer 210 of the first cleaner 200 may be spaced apart from the probe 220 and provided within the thermal conductive body 110. The probe 220 of the first cleaner 200 may contact at least the portion of the thermal conductive body 110. The probe 220 of the first cleaner 200 may transfer the ultrasonic wave to at least the portion of the outer surface 112 of the thermal conductive body 110.

When the thermal conductive body 110 is fixed to the predetermined position on the platen 20, the first cleaner 200 may be provided at a location to clean a side of the outer surface 112 of the thermal conductive body 110 which the platen 20 rotates towards. The first cleaner 200 may be provided at a location to clean a side of the outer surface 112 of the thermal conductive body 110 in which the foreign substances are accumulated due to a rotation of the platen 20. The location may be at a side of the outer surface 112 of the thermal conductive body 110.

As illustrated in FIG. 5, the first cleaner 200 may be provided along a circumference of the outer surface 112 of the thermal conductive body 110. The first cleaner 200 may remove the foreign substances on the circumference of the thermal conductive body 110. The circumference of the thermal conductive body 110 may be an area where the foreign substances easily occur while the thermal conductive body 110 moves. The circumference of the thermal conductive body 110 may include a material capable of transmitting the ultrasonic waves.

The body of the first cleaner 200 may have a ring shape corresponding to the circular shape of the thermal conductive body 110. The probes 220 of the first cleaner 200 may be provided along the circumference of the thermal conductive body 110. The ultrasonic transducer 210 of the first cleaner 200 may be spaced apart from the probes 220 and provided within the thermal conductive body 110. The probes 220 of the first cleaner 200 may contact the thermal conductive body 110 along the circumference of the thermal conductive body 110. The probes 220 of the first cleaner 200 may transmit the ultrasonic wave to the circumference of the outer surface 112. As illustrated in FIGS. 4 and 5, the outer surface of the first cleaner 200 may be the same as the outer surface 112 of the thermal conductive body 110.

When the thermal conductive body 110 rotates or sweeps on the platen 20, the first cleaner 200 may clean the thermal conductive body 110 regardless of a moving direction of the thermal conductive body 110.

As illustrated in FIG. 6, the first cleaner 200 may be provided external to the thermal conductive body 110 and spaced apart from the thermal conductive body 110. The first cleaner 200 may remove the foreign substances on the outer surface 112 of the thermal conductive body 110. The first cleaner 200 may emit and transmit the ultrasonic waves to the thermal conductive body 110.

The body of the first cleaner 200 may have an arc shape corresponding to the circular shape of the thermal conductive body 110. The body of the first cleaner 200 may partially surround and be spaced apart from at least a portion of the circumference of the circular shape through the arc shape.

The body of the first cleaner 200 may be spaced apart from a side of the thermal conductive body 110 for a predetermined distance. The first cleaner 200 may move in the same direction as the thermal conductive body 110 (e.g., the movement of the first cleaner 200 may be coupled to the movement of the thermal conductive body). The first cleaner 200 may move together with the thermal conductive body 110 while the predetermined distance is maintained.

The probes 220 of the first cleaner 200 may be provided to face the thermal conductive body 110 within the body of first cleaner 200. The ultrasonic transducer 210 of the first cleaner 200 may be provided in the body together with the probes 220. The probes 220 of the first cleaner 200 may transfer the ultrasonic waves to the outer surface 112.

In embodiments in which the first cleaner 200 is spaced apart from the side of the thermal conductive body 110, the cleaning nozzle 310 of the second cleaner 300 may be provided on the thermal conductive body 110 and/or a second cleaning nozzle 310A of the second cleaner 300 may be provided on the body of the first cleaner 200. In either case, the cleaning nozzle 310 and/or 310A of the second cleaner 300 may simultaneously clean the body of the first cleaner 200 and the thermal conductive body 110.

In example embodiments, the second cleaner 300 may include a cleaning solution supply, and the cleaning nozzle 310. The second cleaner 300 may spray the cleaning solution 312 onto the thermal conductive body 110 (e.g., the outer surface 112) through the cleaning nozzle 310, and the foreign substances formed on the outer surface 112 of the thermal conductive body 110 may be removed through the cleaning solution 312. As the second cleaner 300 and the first cleaner 200 both perform a function of removing the foreign substances on the outer surface 112 of the thermal conductive body 110, the amount of cleaning solution 312 that the second cleaner 300 may spray onto the thermal conductive body 110 is less than the amount of cleaning solution 312 that the second cleaner 300 may spray onto the thermal conductive body 110 without the inclusion of the first cleaner 200. Additionally, as the second cleaner 300 may spray the cleaning solution 312 onto the thermal conductive body 110 through the cleaning nozzle 310, a dilution of the slurry 32 during the polishing of the substrate W is minimal or minimized in comparison to a substrate polishing apparatus that utilizes a non-contact method of temperature control that sprays a fluid onto a platen.

The cleaning solution supply may supply the cleaning solution 312 to the cleaning nozzle 310. The cleaning solution supply may supply various cleaning solutions to the cleaning nozzle 310 according to a type of the semiconductor substrate W manufactured in the semiconductor manufacturing process.

The cleaning solution may include various fluids capable of removing the foreign substances that remain on the thermal conductive body 110. For example, the cleaning solution may include deionized water (DIW). The cleaning solution may include ammonia (NH₃), sulfuric acid (H₂SO₄), ozone (O₃), hydrofluoric acid (HF), hydrogen peroxide (H₂O₂), and the like. The cleaning solution may be sprayed on the outer surface 112 of the thermal conductive body 110 in liquid state or in gas state (e.g., steam).

The cleaning nozzle 310 may spray the cleaning solution 312 to the outer surface 112 of the thermal conductive body 110. The cleaning nozzle 310 may receive the cleaning solution 312 from the cleaning solution supply.

The cleaning nozzle 310 may have a predetermined angle DE from a direction perpendicular to the surface of the platen 20. The cleaning nozzle 310 may efficiently remove the foreign substances on the outer surface 112 of the thermal conductive body 110 through the predetermined angle DE. For example, the predetermined angle DE may be within a range of 5 degrees to 70 degrees.

The cleaning nozzle 310 may move on the platen 20 together with the thermal conductive body 110. The cleaning nozzle 310 may supply the cleaning solution 312 onto the thermal conductive body 110, and the foreign substances formed on the thermal conductive body 110 may be removed through the cleaning solution 312.

The second cleaner 300 may further include a plurality of the cleaning nozzles 310. The plurality of cleaning nozzles 310 may be arranged along the outer surface 112 of the thermal conductive body 110. The plurality of cleaning nozzles 310 may be arranged along the outer surface 112 of the thermal conductive body 110 to clean the outer surface 112 of the thermal conductive body 110.

In example embodiments, the substrate polishing apparatus 10 may further include a pad conditioner 40. The pad conditioner 40 may spread the slurry 32 on the platen 20. The pad conditioner 40 may restore the surface roughness of the platen 20. The pad conditioner 40 may polish the surface of the platen using a diamond to restore the surface roughness. The pad conditioner 40 may prevent residue remaining on the platen 20 from interfering with supply of the slurry 32.

As described above, the temperature controller 100 of the substrate polishing apparatus 10 may contact the platen 20 to control the temperature on the platen 20. Since the temperature controller 100 is in contact with the platen 20 and the process of heating and cooling of the platen 20 is not accomplished through the application of a fluid (i.e., heating fluid and/or cooling fluid) onto the platen 20, dilution of the slurry 32 through the process of heating and cooling the platen 20 may be prevented. Additionally, since the process of heating and cooling of the platen 20 is not accomplished through the application of a fluid onto the platen 20, wastewater may be reduced.

The first cleaner 200 may transmit the ultrasonic waves that are generated from the ultrasonic transducer 210 to the outer surface of the thermal conductive body 110 through the probe 220. The thermal conductive body 110 may be cleaned through the ultrasonic waves of the first cleaner 200. The ultrasonic wave may remove the foreign substances that are generated from the slurry 32 and the pad residue. The ultrasonic wave may remove the foreign substances without affecting the polishing process.

The substrate polishing apparatus 10 may spray the cleaning solution 312 to the outer surface 112 of the thermal conductive body 110 through the cleaning nozzle 310. The cleaning solution 312 may remove the foreign substances that might not be removed through the ultrasonic waves. The substrate polishing apparatus 10 may efficiently remove the foreign substances on the thermal conductive body 110 through the first and second cleaners 200 and 300. Since the first and second cleaners 200 and 300 remove the foreign substances from the thermal conductive body 110, the temperature controller 100 may efficiently control the temperature of the surface of the platen 20.

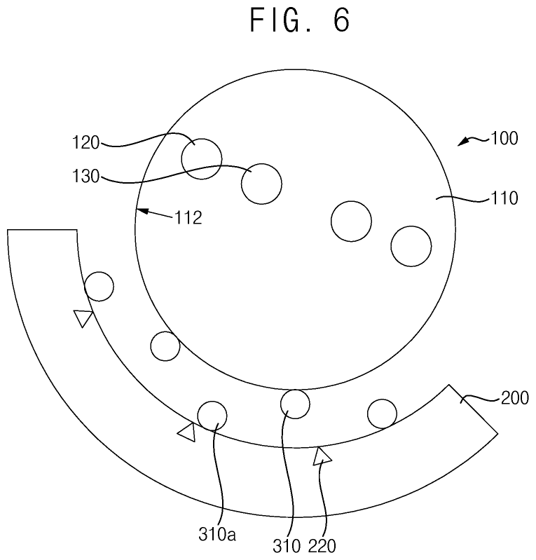

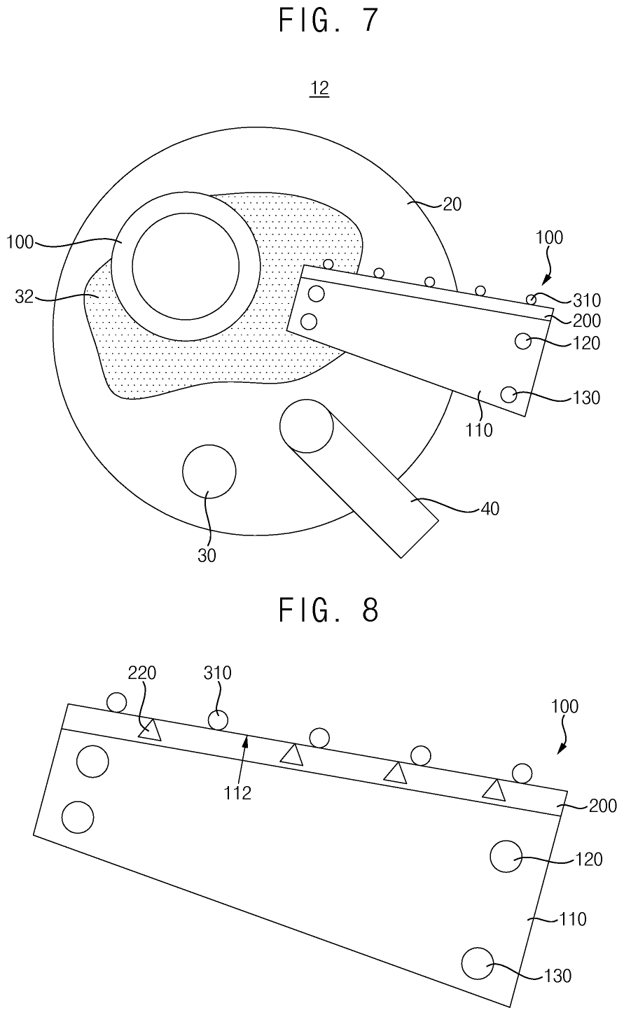

FIG. 7 is a plan view illustrating a substrate polishing apparatus including a thermal conductive body having a trapezoidal shape in accordance with example embodiments. FIGS. 8 to 10 are views illustrating the temperature controller and the cleaner in FIG. 7. The substrate polishing apparatus may be substantially the same as or similar to the substrate polishing apparatus described with reference to FIGS. 1 to 6 except for a configuration of the thermal conductive body. Thus, same or similar components that may be denoted by the same or similar reference numerals, and repeated descriptions of the same components may be omitted.

Referring to FIGS. 1 to 10, a substrate polishing apparatus 12 may include the platen 20 configured to support the semiconductor substrate W, the slurry supply 30 configured to supply the slurry 32 between the semiconductor substrate W and the platen 20, the substrate holder 50 configured to hold and fix the semiconductor substrate W on the platen 20 such that the semiconductor substrate W is in contact with the platen 20, the temperature controller 100 configured to control the temperature of the platen 20 through the thermal conductive body 110, the first cleaner 200 configured to remove the foreign substances on the thermal conductive body 110 through the ultrasonic waves, and the second cleaner 300 having the at least one cleaning nozzle 310 capable of removing the foreign substances on the thermal conductive body 110 through the cleaning solution.

The temperature controller 100 may include the thermal conductive body 110 capable of controlling the temperature of the platen 20 in contact with the platen 20, the first fluid transfer line 120 capable of absorbing the heat from the thermal conductive body 110, and the second fluid transfer line 130 capable of supplying the heat to the thermal conductive body 110.

The temperature controller 100 may further include the actuator capable of sweeping the thermal conductive body 110. The actuator may move the thermal conductive body 110 on the platen 20. The actuator may be fixed to one side of the thermal conductive body 110 to move the thermal conductive body 110. Alternatively, the thermal conductive body 110 may be fixed to a predetermined position on the platen 20.

The thermal conductive body 110 may contact the surface of the platen 20 to control the temperature. The thermal conductive body 110 may control the heat through the lower surface in contact with the surface of the platen 20. For example, the thermal conductive body 110 may have a trapezoidal shape.

As illustrated in FIG. 8, the first cleaner 200 may be provided along at least a portion of the outer surface 112 of the thermal conductive body 110. The first cleaner 200 may be provided along one side of the trapezoidal shape of the thermal conductive body 110.

The body of the first cleaner 200 may remove the foreign substances on the one side of the trapezoidal shape of the thermal conductive body 110. The one side of the trapezoidal shape of the thermal conductive body 110 may be referred to as an area where the foreign substances easily occur while the thermal conductive body 110 sweeps. For example, the one side of the trapezoidal shape of the thermal conductive body 110 may include a material capable of transmitting the ultrasonic wave.

The body of the first cleaner 200 may have a rod shape corresponding to the trapezoidal shape of the thermal conductive body 110. The probe 220 of the first cleaner 200 may be provided on the one side of the trapezoidal shape of the thermal conductive body 110. The ultrasonic transducer 210 of the first cleaner 200 may be spaced apart from the probe 220 and provided within the thermal conductive body 110. The probe 220 of the first cleaner 200 may transmit the ultrasonic waves to the one side of the trapezoidal shape.

When the thermal conductive body 110 is fixed to the predetermined position on the platen 20, the first cleaner 200 may be provided at a side of the thermal conductive body in a direction in which the platen 20 rotates towards. The first cleaner 200 may be provided on the thermal conductive body 110 toward a direction in which the foreign substances are accumulated due to a rotation of the platen 20.

As illustrated in FIG. 9, the first cleaner 200 may be provided along the circumference of the outer surface 112 of the thermal conductive body 110. The first cleaner 200 may be provided along a circumference of trapezoidal shape of the thermal conductive body 110.

The body of the first cleaner 200 may remove the foreign substances on the circumference of the trapezoidal shape of the thermal conductive body 110. The circumference of the trapezoidal shape of the thermal conductive body 110 may be referred to as an area where the foreign substances easily occur while the thermal conductive body 110 sweeps. For example, the circumference of the trapezoidal shape of the thermal conductive body 110 may include a material capable of transmitting the ultrasonic waves.

The body of the first cleaner 200 may have a ring shape corresponding to the trapezoidal shape of the thermal conductive body 110. The probe 220 of the first cleaner 200 may be provided on the circumference of the trapezoidal shape of the thermal conductive body 110. The ultrasonic transducer 210 of the first cleaner 200 may be spaced apart from the probe 220 and provided within the thermal conductive body 110. The probe 220 of the first cleaner 200 may transmit the ultrasonic wave to the circumference of the trapezoidal shape.

When the thermal conductive body 110 sweeps on the platen 20, the first cleaner 200 may clean the thermal conductive body 110 regardless of the moving direction of the thermal conductive body 110.

As illustrated in FIG. 10, the first cleaner 200 may be provided and spaced apart from the thermal conductive body 110. The first cleaner 200 may remove the foreign substances on the outer surface 112 of the thermal conductive body 110. The first cleaner 200 may emit and transmit the ultrasonic waves to the thermal conductive body 110.

The first cleaner 200 may have the rod shape corresponding to the trapezoidal shape of the thermal conductive body 110. The thermal conductive body 110 may surround and be spaced apart from at least a portion of the circumference of the trapezoidal shape through the rod shape.

The body of the first cleaner 200 may be spaced apart from the trapezoidal shape of the thermal conductive body 110 for a predetermined distance. The first cleaner 200 may move in the same direction as the thermal conductive body 110. The first cleaner 200 may move together with the thermal conductive body 110 while the predetermined distance is maintained.

The probes 220 of the first cleaner 200 may be provided to face the thermal conductive body 110 within the body. The ultrasonic transducer 210 of the first cleaner 200 may be provided in the body together with the probes 220. The probes 220 of the first cleaner 200 may transfer the ultrasonic waves to the outer surface 112.

The cleaning nozzle 310 of the second cleaner 300 may be provided on the body of the first cleaner 200. In this case, the cleaning nozzle 310 of the second cleaner 300 may simultaneously clean the body of the first cleaner 200 and the thermal conductive body 110.

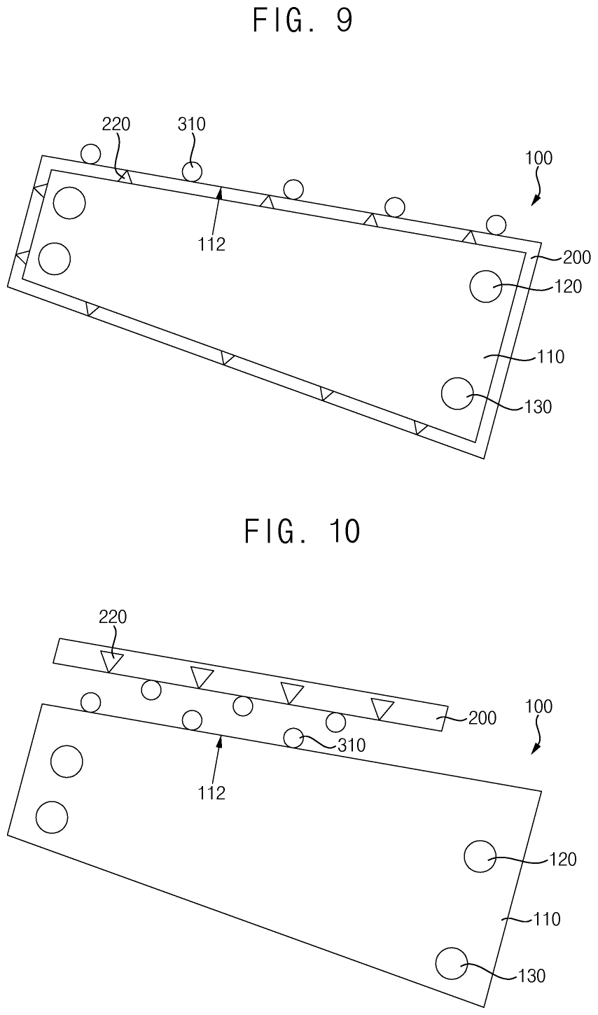

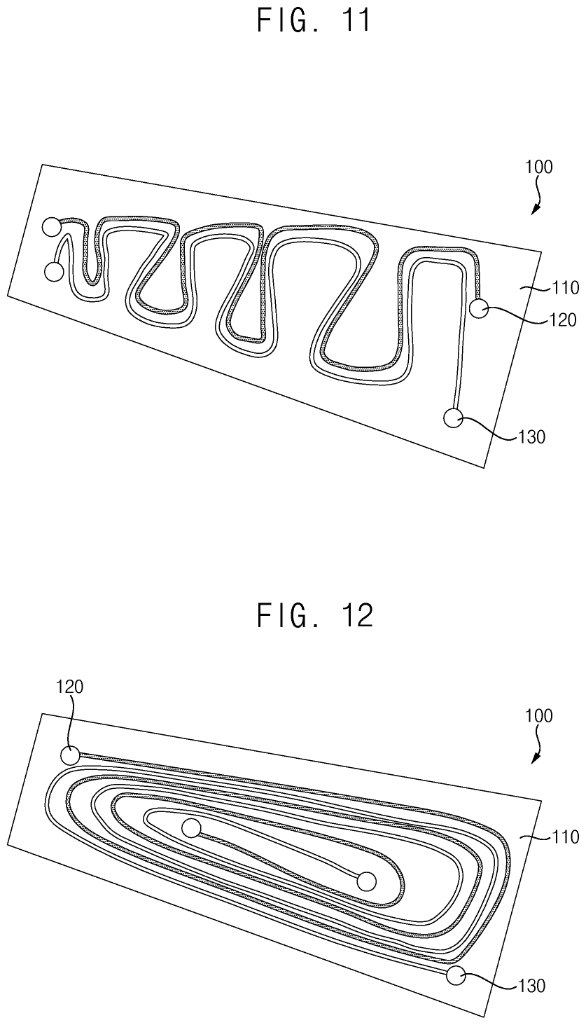

FIG. 11 is a view illustrating a temperature controller including fluid transfer lines having a meandering arrangement. FIG. 12 is a view illustrating a temperature controller including fluid transfer lines having a spiral arrangement.

Referring to FIGS. 11 and 12, the first and second fluid transfer lines 120 and 130 of the temperature controller 100 may include a meandering arrangement extending in a zigzag pattern, or a spiral arrangement.

The first and second fluid transfer lines 120 and 130 may have the meandering arrangement or the spiral arrangement, respectively. The first and second fluid transfer lines 120 and 130 may extend parallel to each other. The first and second fluid transfer lines 120 and 130 may extend in a direction to minimize an empty space within the thermal conductive body 110. The first and second fluid transfer lines 120 and 130 may increase a contact area between the first and second fluid transfer lines 120 and 130 with the lower surface of the thermal conductive body 110 through the meandering arrangement or the spiral arrangement. The first and second fluid transfer lines 120 and 130 may increase an amount of heat moving from the thermal conductive body 110 through the meandering arrangement or the spiral arrangement.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

1. A substrate polishing apparatus, comprising:
a platen having a surface configured to polish a semiconductor substrate through relative movement between the platen and the semiconductor substrate;
a slurry supply configured to supply slurry to the platen, wherein the slurry flows to a location between the semiconductor substrate and the platen;
a substrate holder configured to grip and fix the semiconductor substrate to be in contact with the platen such that the platen contacts the surface of the semiconductor substrate to be polished;
a temperature controller having a thermal conductive body that is configured to contact the surface of the platen to transfer heat between the thermal conductive body and the platen to control the temperature of the platen; and
a first cleaner having an ultrasonic transducer and at least one probe, the ultrasonic transducer configured to generate ultrasonic waves and the probe configured to transmit the ultrasonic waves to an outer surface of the thermal conductive body.

2. The substrate polishing apparatus of claim 1, further comprising:
a second cleaner having at least one cleaning nozzle, the cleaning nozzle configured to spray a cleaning solution to the outer surface of the thermal conductive body.

3. The substrate polishing apparatus of claim 2, wherein the cleaning nozzle has a predetermined angle from a direction perpendicular to the surface of the platen, and
the predetermined angle is within a range of 5 degrees to 70 degrees.

4. The substrate polishing apparatus of claim 2, wherein the second cleaner further includes a plurality of the cleaning nozzles, and
the plurality of cleaning nozzles are arranged along the outer surface of the thermal conductive body.

5. The substrate polishing apparatus of claim 1, wherein the temperature controller includes,
a first fluid transfer line through which cooling fluid moves along a lower surface of the thermal conductive body; and
a second fluid transfer line through which heating fluid moves along the lower surface of the thermal conductive body.

6. The substrate polishing apparatus of claim 5, wherein each of the first and second fluid transfer lines includes a meandering arrangement extending in a zigzag pattern, or a spiral arrangement.

7. The substrate polishing apparatus of claim 1, wherein the thermal conductive body includes a circular shape or a trapezoidal shape.

8. The substrate polishing apparatus of claim 1, wherein the thermal conductive body rotates or sweeps on the platen.

9. The substrate polishing apparatus of claim 1, wherein the probe is provided in the thermal conductive body to transmit the ultrasonic waves to the thermal conductive body.

10. The substrate polishing apparatus of claim 1, wherein the ultrasonic transducer and the probe are provided on the thermal conductive body, and
the probe contacts the outer surface of the thermal conductive body to transmit the ultrasonic waves.

11. A substrate polishing apparatus, comprising:
a platen having a surface configured to polish a semiconductor substrate through relative movement between the platen and the semiconductor substrate;
a slurry supply configured to supply slurry between the semiconductor substrate and the platen;
a substrate holder configured to grip and fix the semiconductor substrate to be in contact with the platen such that the platen contacts the surface of the semiconductor substrate to be polished;
a temperature controller in contact with the surface of the platen, the temperature controller having a thermal conductive body that is configured to absorb or dissipate heat from the surface of the platen;
a first cleaner having an ultrasonic transducer and at least one probe, the ultrasonic transducer configured to generate ultrasonic waves, the probe contacting the thermal conductive body to transmit the ultrasonic waves to the thermal conductive body; and
a second cleaner having a plurality of cleaning nozzles that are configured to spray a cleaning solution on an outer surface of the thermal conductive body.

12. The substrate polishing apparatus of claim 11, wherein
each of the plurality of cleaning nozzles has a predetermined angle from a direction perpendicular to the surface of the platen, and
the predetermined angle is within a range of 5 degrees to 70 degrees.

13. The substrate polishing apparatus of claim 11, wherein the plurality of cleaning nozzles are arranged along an outer surface of the thermal conductive body.

14. The substrate polishing apparatus of claim 11, wherein the temperature controller includes,
a first fluid transfer line through which cooling water moves along a lower surface of the thermal conductive body; and
a second fluid transfer line through which heating water moves along the lower surface of the thermal conductive body.

15. The substrate polishing apparatus of claim 14, wherein each of the first and second fluid transfer lines includes a meandering arrangement extending in a zigzag pattern, or a spiral arrangement.

16. The substrate polishing apparatus of claim 11, wherein the thermal conductive body includes a circular shape or a trapezoidal shape.

17. The substrate polishing apparatus of claim 11, wherein the thermal conductive body rotates or sweeps on the platen.

18. The substrate polishing apparatus of claim 11, wherein the probe is provided in the thermal conductive body to transmit the ultrasonic waves to the thermal conductive body.

19. The substrate polishing apparatus of claim 11, wherein the ultrasonic transducer and the probe are provided on the thermal conductive body, and the probe contacts the outer surface of the thermal conductive body to transmit the ultrasonic waves.

20. A substrate polishing apparatus, comprising:
a platen having a surface configured to polishing a semiconductor substrate through interaction between the platen and the semiconductor substrate using a slurry that is supplied on the surface of the platen;
a substrate holder configured to grip and fix the semiconductor substrate to be in contact with the platen such that the platen contacts the surface of the platen semiconductor substrate to be polished;
a temperature controller having a thermal conductive body that is configured to in contact with the platen to transfer heat between the surface of the platen and the thermal conductivity body;
a first cleaner configured to generate ultrasonic waves on an outer surface of the thermal conductive body to remove foreign substances that are formed on the outer surface; and
a second cleaner configured to spray a cleaning solution on the outer surface of the thermal conductive body at a predetermined angle from a direction perpendicular to the surface of the platen to remove the foreign substances.

21. (canceled)
